(19) United States
(12) Patent Application Publication
(10) Pub. No.: US 2011/0076464 A1
(43) Pub. Date: Mar. 31, 2011

(54) STRUCTURING OF CONDUCTIVE POLYMER LAYERS BY MEANS OF THE LIFT-OFF PROCESS

(75) Inventors: Andreas Elschner, Muelheim (DE); Wilfried Loevenich, Bergisch-Gladbach (DE); Kerstin Pollock, Dinslaken (DE)

(73) Assignee: H.C. Starck Clevios GmbH, Goslar (DE)

(21) Appl. No.: 12/745,409

(22) PCT Filed: Nov. 3, 2008
(86) PCT No.: PCT/EP08/64879

§ 371 Date: Nov. 24, 2010

(30) Foreign Application Priority Data
Nov. 28, 2007 (DE) 10 2007 057 650.3

(51) Int. Cl. B32B 3/10; G03F 7/20

(52) U.S. Cl. 428/195.1; 430/311

(57) ABSTRACT

Processes comprising: (a) providing a substrate; and (b) forming a conductive structured polymer layer on a surface of the substrate, wherein forming the conductive structured polymer layer comprises applying at least one conductive polymer comprising a polycation and at least one polyanion having a mean molecular weight M_{w} of 1,000 to 100,000 g/mol using a lift-off process; and structured conductive layers prepared thereby.

The invention relates to a process for producing conductive structured polymer layers by means of the lift-off process, and to the conductive structured polymer layers produced by this process.

In the last few years, conductive polymers have gained economic significance owing to an improved profile of properties. Increasing the electrical conductivity on the one hand and improving the chemical stability to environmental influences on the other hand allowed many new applications to be developed. For example, conductive polymers are being used with increasing success as antistatic layers, transparent electrodes, hole injection layers, counter electrodes in capacitors or sensors.

For many applications in which conductive polymers are used or could be used, it is necessary to structure the conductive polymer layer. Structuring of a polymer layer is understood to mean that the layer is not deposited homogeneously over the whole area of a carrier, for example a film or a glass plate, but rather consists of individual segments, for example individual conductor tracks, which are spatially separate from one another and hence electrically insulated from one another. The challenge is thus to apply these three-dimensional lateral structures on a support with maximum spatial resolution. What is meant by this is that the regions in which the conductive polymer is present as a layer and the regions in which no polymer is present are sharply delimited from one another. The step which arises at the boundary of the regions determines the spatial resolution. This can be characterized by two parameters, the step height h and the step width b. The step height corresponds to the thickness of the polymer layer and is typically 30 nm<h<10 μm. The step width corresponds to the width of the polymer layer, a step width b of <20 μm, preferably of b <5 μm, being necessary for many applications. These include, for example, electrodes for organic light-emitting diodes “OLEDs” (Organic Light Emitting Devices, Ed. Joseph Shinar, 2004 Springer-Verlag) or electrodes for organic field-effect transistors “OFETs” (Organic Electronics, Ed. Hagen Klauk, 2006 Wiley-VCH, p. 3ff), which are separated from one another by only a few μm.

In order to apply conductive polymers to a carrier in a laterally structured manner, various printing processes are currently being developed. The printing processes which are considered to be particularly suitable include inkjet, screen, flexographic, pad, offset and gravure printing (Organic Electronics, Ed. Hagen Klauk, 2006 Wiley-VCH, p. 297 ff). These printing processes are established and have been found to be useful in the deposition of suitable printing inks. However, since these printing techniques have been developed primarily for visualizing printed images, their lateral resolution is restricted to the separation sharpness of the naked eye, i.e. the step width here is typically b>20 μm.

For many interesting applications of conductive polymers, however, a step width b of <20 μm is needed. Especially the structures discussed under the heading “polymeric electronics”, in which, among other structures, field-effect transistors are constructed completely from polymers, require significantly finer structures than the established printing techniques are currently capable of providing.

Furthermore, the established printing processes listed above lead to printed images in which the deposited inks or dyes have surfaces which are often inhomogeneous and have microscopic roughness. For instance, screenprinting, flexographic printing, pad printing, offset printing and gravure printing require high-viscosity inks per se, which then can no longer run sufficiently during drying and hence form rough surfaces. Rough surfaces of conductive polymer layers with a mean roughness Ra>5 nm are, however, undesired especially in OLEDs or OFETs, since they can lead to electrical short circuits here. In the case of inkjet printing, in contrast, low-viscosity inks with good running are used, but here the so-called “coffee-drop effect” (Tekin, Emine; de Gans, Berend-Jan; Schubert, Ulrich S., Journal of Materials Chemistry (2004), 14(17), 2627-2632) leads to the effect that the layer thickness at the edge of the deposited droplet is significantly higher than in the centre. This effect makes the generation of homogeneous conductive polymer layers, such as areas or lines, likewise difficult.

One means of depositing conductive polymers in structures with high spatial resolution, i.e. with a step width b of <20 μm, the polymer surfaces being smooth, i.e. the mean roughness Ra being less than 5 nm, is described in EP-A-1079397. In this case, homogeneous layers of a conductive polymer which are applied by means of a spin-coater are structured by means of a laser beam. The laser beam of an excimer or Nd:YAG laser is conducted over the sites at which the polymer has to be removed and destroys the organic layer at the appropriate sites (laser ablation). This process is currently only being used to remove polymer layers from glass substrates and has the disadvantage that it is slow and expensive owing to the purchasing and operating costs of the laser. An additional disadvantage is that the ablated fragments of the polymer are deposited on, i.e. contaminate, the surface of the adjacent polymer layer, and these fragments can alter the electrical properties and surface properties of the conductive polymer. It is likewise disadvantageous that the laser ablation of conductive polymers on polymeric substrates, for example polyethylene terephthalate (PET) films, can be controlled only with difficulty, since the substrate material is simultaneously also ablated in the course of the desired removal of the conductive polymer. The resolution capacity in laser structuring is limited to the focussability of the laser beam and is 1-5 μm.

DE-A-10340641 describes the structuring of conductive polymers by means of photolithography. Here, a positive photoresist layer is applied to the conductive polymer layer and exposed through a shadowmask. The photoresist can be removed with a developer at the exposed sites and thus exposes the conductive polymer layer below it. This can then be removed by placing it in to a suitable solvent. The desired conductive polymer structures are exposed by solubilizing the insoluble photoresist thereon by large-area UV irradiation, so-called flood exposure, and removed with the developer by subsequent rinsing. This process has the following disadvantages: the conductive polymer layer comes into direct contact with the photoresist, i.e. the photoresist can contaminate the conductive polymer layer and thus alter its electronic properties, for example the work function. A further disadvantage is that the flood exposure can permanently damage the conductive polymer by photooxidation and the conductivity is thus lowered.

A further method of structuring conductive polymers is described by Hohnholz, Okuzaki and MacDiarmid (“Plastic Electronic Devices Through Line Patterning of Conducting Polymers”, Advanced Materials, 2005, 15, 51-56). In this method, polyethylenedioxythiophene/polystyrene-sulphonic acid (PEDOT/PSS) is structured by applying this conductive polymer to film which has been provided beforehand with a pattern of baked toner by means of a laser printer. Removal of the tone in toluene or acetone likewise removes the PEDOT/PSS layer above it, but the conductive polymer remains on the regions of the film which do not contain any toner. Although this method is simple, it has the disadvantage that, owing to the granularity of the toner particles, only coarse structures with a step width b of >50 μm can be achieved.

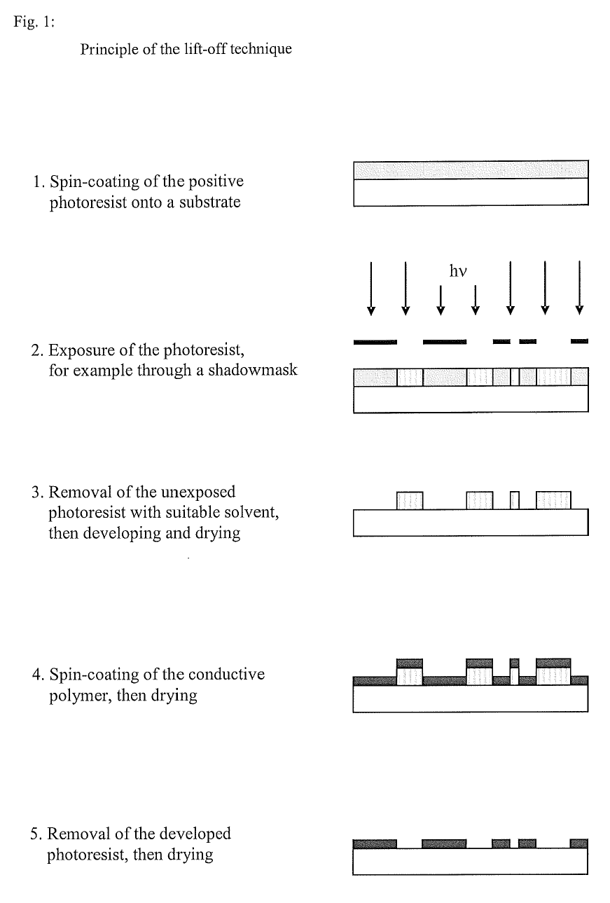

Dong, Zhong, Chi and Fuchs describe, in “Patterning of Conducting Polymers Based on a Random Copolymer Strategy: Toward the Facile Fabrication of Nanosensors Exclusively Based on Polymers” (Advanced Materials, 2005, 17, 2736-2741), another approach by which conductive polymers can be structured. The process employed here is that of lift-off processing known from photolithography (cf. “Lithographic Processes”, Brochure from MicroChemicals GmbH of 2005, cf. FIG. 1). In this process, a positive photoresist is first applied to the substrate and exposed to an electron beam at the points at which no conductive polymer is to cover the surface later. The unexposed photoresist is then removed with solvent. The exposed photoresist is then cured thermally, such that it forms a negative of the structure which is desired later. Pyrroles or anilines are then applied by spin-coating as a thin film from solution in the presence of the oxidizing agent FeCl₃, and polymerized to completion on the substrate. This film is then present both on the hardened photoresist and at the points on the substrate which have been freed from the photoresist. Rinsing in toluene or acetone then allows the hardened photoresist to be removed again, such that the layer of conductive polymer above it is also removed. The conductive polymer which is insoluble in toluene or acetone remains adhering on the substrate at the points free of the photoresist. The lift-off process can be used to achieve structures of conductive polymers with a step width of <1 μm. However, a disadvantage in the process described is that the conductive polymers have to be polymerized in situ on the substrate, i.e. a chemical reaction proceeds on the substrate, which can be implemented on the industrial scale only with a high level of complexity. Layers polymerized in situ additionally have the disadvantage of forming only moderately smooth surfaces and of tending to flake off owing to their tension.

There was thus still a need for a process for producing conductive structured polymer layers, in which the conductive polymer can be deposited on a substrate from solution or dispersion, in which the structures of the conductive polymer layer give rise to a high lateral spatial resolution, and in which the surfaces of the conductive polymer layer are smooth. In addition, there was a need for a process for structuring high-conductivity polymers, i.e. polymers with a conductivity of σ>100 S/cm, for example for the production of field-effect transistors or sensors. Here, the separation of adjacent electrodes d must be as low as possible; d is preferably <500 μm.

It was therefore an object of the invention to provide a process for producing conductive structured polymer layers, in which the conductive polymer can be deposited on a substrate from solution or dispersion, in which the structures of the conductive polymer layer give rise to a high lateral spatial resolution, and in which the surfaces of the conductive polymer layer are smooth. It was a further object of the invention to provide a process for structuring high-conductivity polymers, i.e. polymers with a conductivity of σ>100 S/cm.

It has now been found that, surprisingly, conductive structured polymer layers which satisfy the abovementioned conditions can be produced using the lift-off process and with application of at least one conductive polymer as a polycation and at least one polyanion to the substrate.

The present invention therefore provides a process for producing conductive structured polymer layers using the lift-off process, characterized in that at least one conductive polymer as a polycation and at least one polyanion which has a mean molecular weight M_{w} within a range of 1000 to 100 000 g/mol are applied to the substrate.

In this context, the lift-off process comprises the steps shown in FIG. 1. This process can be used to generate structures with a step width b of <5 μm.

In the context of the invention, conductive polymers as the polycation may be an optionally substituted polythiophene, polyaniline or polypyrrole. It may also be the case that mixtures of two or more of these conductive polymers are used as the polycation.

In a preferred embodiment, the polycation is an optionally substituted polythiophene containing repeat units of the general formula (I)

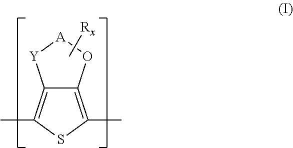

where
A is an optionally substituted C₁-C₅-alkylene radical, preferably an optionally substituted C₂-C₃-alkylene radical,
Y is O or S,
R is a linear or branched, optionally substituted C₁-C₁₈-alkyl radical, preferably linear or branched, optionally substituted C₁-C₁₄-alkyl radical, an optionally substituted C₃-C₁₂-cycloalkyl radical, an optionally substituted C₆-C₁₄-aryl radical, an optionally substituted C₇-C₁₈-aralkyl radical, an optionally substituted C₁-C₄-hydroxyalkyl radical or a hydroxyl radical,
x is an integer of 0 to 8, preferably 0, 1 or 2, more preferably 0 or 1, and,
   in the case that a plurality of R radicals is bonded to A, they may be the same or different.

The general formula (I) should be understood such that the substituent R may be bonded x-times to the alkylene radical A.

In further preferred embodiments, the polycation may be a polythiophene containing repeat units of the general formula (I-a) and/or of the general formula (I-b)

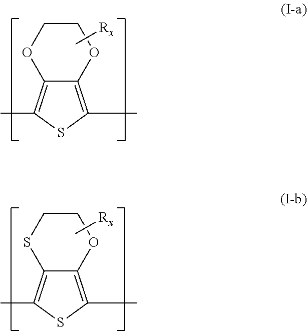

in which

R and x are each as defined above.

In yet further preferred embodiments, the polycation is a polythiophene containing repeat units of the general formula (I-aa) and/or of the general formula (I-ba)

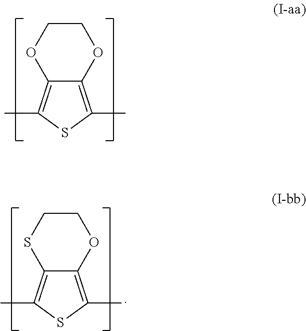

In the context of the invention, the prefix “poly-” is understood to mean that more than one identical or different repeat unit is present in the polythiophene. The polythiophenes contain a total of n repeat units of the general formula (I), where n may be an integer of 2 to 2000, preferably 2 to 100. The repeat units of the general formula (I) may each be the same or different within a polythiophene. Preference is given to polythiophenes containing in each case identical repeat units of the general formula (I).

On the end groups, the polythiophenes preferably each bear H.

In particularly preferred embodiments, the polycation is poly(3,4-ethylenedioxythiophene) or poly(3,4-ethyleneoxythiathiophene), i.e. a homopolythiophene foamed from repeat units of the formula (I-aa) or (I-ba).

In further particularly preferred embodiments, the polycation is a copolymer formed from repeat units of the formula (I-aa) and (I-ba).

In the context of the invention, C₁-C₅-alkylene radicals A are methylene, ethylene, n-propylene, n-butylene or n-pentylene, in the context of the invention, C₁-C₁₈-alkyl represents linear or branched C₁-C₁₈-alkyl radicals, for example methyl, ethyl, n- or isopropyl, n-, iso-, sec- or tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, n-octyl, 2-ethylhexyl, n-nonyl, n-decyl, n-undecyl, n-dodecyl, n-tridecyl, n-tetradecyl, n-hexadecyl or n-octadecyl; C₅-C₁₂-cycloalkyl represents C₅-C₁₂-cycloalkyl radicals such as cyclopentyl, cyclohexyl, cycloheptyl, cyclooctyl, cyclononyl or cyclodecyl, C₆-C₁₄-aryl radicals represents, for example, phenyl or naphthyl, and C₇-C₁₈-aralkyl represents C₇-C₁₈-aralkyl radicals, for example benzyl, o-, m-, p-tolyl, 2,3-, 2,4-, 2,5-, 2,6-, 3,4-, 3,5-xylyl or mesityl. In the context of the invention, C₁-C₄-hydroxyalkyl radical represents the above-listed C₁-C₄-alkyl radicals with one hydroxyl group. The above list serves to illustrate the invention and should not be considered to be exclusive.

Possible optional further substituents of the above radicals include numerous organic groups, for example alkyl, cycloalkyl, aryl, halogen, ether, thioether, disulphide, sulphoxide, sulphone, sulphonate, amino, aldehyde, keto, carboxylic ester, carboxylic acid, carbonate, carboxylate, cyano, alkylsilane and alkoxysilane groups, and also carboxylamide groups.

The polycations, especially the polythiophenes, are cationic, “cationic” relating only to the charges which reside on the polythiophene backbone. According to the substituent on the R radicals, the polythiophenes may bear positive and negative charges in the structural unit, the positive charges being present on the polythiophene backbone and the negative charges, if any, on the R radicals substituted by sulphonate or carboxylate groups. The positive charges of the polythiophene backbone may be partially or completely saturated by any anionic groups present on the R radicals. Viewed overall, the polythiophenes in these cases may be cationic, uncharged or even anionic. Nevertheless, they are all considered to be cationic polythiophenes in the context of the invention, since the positive charges on the polythiophene backbone are crucial. The positive charges are not shown in the formulae, since their exact number and position cannot be stated unambiguously. The number of positive charges is, however, at least 1 and at most n, where n is the total number of all repeat units (identical or different) within the polythiophene.

To compensate for the positive charge, if this has not already been done by any sulphonate or carboxylate-substituted and thus negatively charged R radicals, the polycations or cationic polythiophenes require anions as counterions.

Useful counterions are preferably polymeric anions, also referred to hereinafter as polyanions.

Suitable polyanions include, for example, anions of polymeric carboxylic acids, such as polyacrylic acids, polymethaciylic acid or polymaleic acids, or anions of polymeric sulphonic acids such as polystyrenesulphonic acids and polyvinylsulphonic acids. These polycarboxylic and polysulphonic acids may also be copolymers of vinylcarboxylic and vinylsulphonic acids with other polymerizable monomers, such as acrylic esters and styrene. These may, for example, also be partly fluorinated or perfluorinated polymers containing SO₃⁻M⁺ or COO⁻M⁺ groups, where M⁺ is, for example, Li⁺, Na⁺, K⁺, Rb⁺, Cs⁺ or NH₄⁺, preferably H⁺, Na⁺ or K⁺.

A particularly preferred polymeric anion is the anion of polystyrenesulphonic acid (PSS).

Cationic polythiophenes which contain anions as counterions for charge compensation are often also referred to in the technical field as polythiophene/(poly)anion complexes.

In particularly preferred embodiments of the invention, the polycation is 3,4-(ethylenedioxythiophene) and the polyanion is polystyrenesulphonate.

The mean molecular weight M_{w} (weight-average) of the polyacids which provide the polyanions, preferably of the polystyrenesulphonic acid, is preferably within a range of 20 000 to 70 000 g/mol, more preferably within a range of 30 000 to 60 000 g/mol. The polyacids or alkali metal salts thereof are commercially available, for example polystyrenesulphonic acids and polyacrylic acids, or else are preparable by known processes (see, for example, Houben Weyl, Methoden der organischen Chemie [Methods of Organic Chemistry], Vol. E 20 Makromolekulare Stoffe [Macromolecular Substances], part 2, (1987), p. 1141ff.).

The mean molecular weight M_{w} is determined by means of aqueous gel permeation chromatography (GPC), using a phosphate buffer as the eluent and an MCX column combination. The detection is effected here by means of an RI detector. The signals are evaluated using polystyrenesulphonic acid calibration at 25° C.

In yet a further preferred embodiment, the conductive polymer layers comprising at least one polycation and at least one polyanion can be applied to the substrate in the form of a dispersion or solution. Examples of suitable processes for applying the conductive polymer layers are processes such as spin-coating, knife-coating, dip- and spray-coating, or printing processes such as inkjet, offset, gravure and flexographic printing; preference is given to spin-coating.

Suitable substrates are glass, silicon wafers, paper and polymer films, such as polyester, polyethylene terephthalate, polyethylene naphthalate, polycarbonate, polyacrylate, polysulphone or polyimide films.

The conductive polymer layers applied form homogeneous layers with a mean roughness of the surface of typically Ra<5 nm. This value can be determined by means of an atomic force microscope (Digital Instruments) over an area of 1 μm². The electrical conductivity of the layers is preferably σ=500 S/cm. This value can be calculated from the measured surface resistivity R_{sq} and the layer thickness d according to σ=(R_{sq}·d)⁻¹. To this end, two parallel Ag electrodes are vapour-deposited onto the layer and the electrical resistance R between them is measured. For the surface resistivity, R_{sq}=R W/L where L is the electrode separation and W is the electrode length. The layer thickness d is determined with a stylus profilometer (Tencor 500) at the level of a scratch in the polymer layer.

In the context of the invention, the dispersion or solution may be aqueous or alcoholic.

“Alcoholic” is understood to mean that a mixture comprising water and alcohol(s) is used. Suitable alcohols are, for example, aliphatic alcohols such as methanol, ethanol, i-propanol and butanol.

These dispersions or solutions may additionally comprise at least one polymeric binder. Suitable binders are polymeric, organic binders, for example polyvinyl alcohols, polyvinylpyrrolidones, polyvinyl chlorides, polyvinyl acetates, polyvinyl butyrates, polyacrylic esters, polyacrylamides, polymethacrylic esters, polymethacrylamides, polyacrylonitriles, styrene/acrylic ester, vinyl acetate/acrylic ester and ethylene/vinyl acetate copolymers, polybutadienes, polyisoprenes, polystyrenes, polyethers, polyesters, polycarbonates, polyurethanes, polyamides, polyimides, polysulphones, melamine-formaldehyde resins, epoxy resins, silicone resins or celluloses. The solids content of polymeric binder is between 0 and 3 percent by weight (% by weight), preferably between 0 and 1% by weight.

The dispersions or solutions may additionally comprise adhesion promoters, for example organofunctional silanes or hydrolysates thereof, for example 3-glycidoxypropyltrialkoxysilane, 3-aminopropyltriethoxysilane, 3-mercaptopropyltrimethoxysilane, 3-methacryloxypropyltriethoxysilane, vinyltrimethoxysilane or octyltriethoxysilane.

In order to enhance the conductivity of the abovementioned dispersions or solutions, it is possible in the context of the invention to add conductivity enhancers such as dimethyl sulphoxide thereto. However, other conductivity enhancers, as disclosed in EP 0686662 or by Ouyang et al., Polymer, 45 (2004), p. 8443-8450, can also be used as conductivity enhancers in the context of the invention. Suitable conductivity enhancers are particularly compounds containing ether groups, for example tetrahydrofuran, compounds containing lactone groups such as γ-butyrolactone, γ-valerolactone, compounds containing amide or lactam groups, such as caprolactam, N-methylcaprolactam, N,N-dimethylacetamide, N-methylacetamide, N,N-dimethylformamide (DMF), N-methylformamide, N-methylformanilide, N-methylpyrrolidone (NMP), N-octylpyrrolidone, pyrrolidone, sulphones and sulphoxides, for example sulpholane (tetramethylenesulphone), dimethyl sulphoxide (DMSO), sugars or sugar derivatives, for example sucrose, glucose, fructose, lactose, sugar alcohols, for example sorbitol, mannitol, furan derivatives, for example 2-furancarboxylic acid, 3-furancarboxylic acid, and/or di- or polyalcohols, for example ethylene glycol, glycerol, di- or triethylene glycol. Particular preference is given to using, as conductivity-enhancing additives, tetrahydrofuran, N-methylformamide, N-methylpyrrolidone, dimethyl sulphoxide or sorbitol.

In the context of the invention, the polycation(s) and polyanion(s) may be present in a weight ratio of 1:2 to 1:7, preferably of 1:2.5 to 1:6.5 and more preferably of 1:3 to 1:6. The weight of the polycation corresponds here to the initial weight of the monomers used, assuming that the monomer is converted fully in the polymerization.

The present invention further provides the conductive structured polymer layers produced by the process according to the invention.

The step width b of the conductive polymer layer produced by the process according to the invention is preferably less than 5 μm, more preferably less than 1 μm. The step widths achieved can be determined with a stylus profilometer (Tencor 500). The steps of the structured conductive polymer layers produced by the process according to the invention had a width b of <5 μm. Snce this width corresponds to the lateral resolution capability of the stylus profilometer, it can be assumed that the true step width is actually even less than 5 μm.

The examples which follow serve to illustrate the invention merely of example and should in no way be interpreted as a restriction.

### EXAMPLES

### Example 1

A glass substrate of size 50 mm×50 mm was cleaned first with acetone, then with Mucasol solution in an ultrasound bath and finally in a UV/ozone reactor (UPV, Inc.; PR-100). The AZ 1512 HS photoresist (MicroChemicals GmbH) was then applied to the glass substrate by spin-coating with a spin-coater (Carl Suss, RC8) at 1000 rpm for 30 seconds (sec.) at an acceleration of 200 rev/sec² and with the lid open. The film which formed was dried first on a hotplate at 100° C. for 3 minutes (min.) and then at 115° C. in a drying cabinet for 30 minutes. After the drying, the layer thickness d was 2.8 μm (cf. FIG. 1-1).

The photoresist-coated substrate was covered with a shadowmask, consisting of a nickel film of thickness 50 μm with recesses of width 100-400 μm, and exposed to UV light in a photoresist illuminator (from Walter Lemmen, Kreuzwertheim, Aktina E) for 80 seconds (sec.). Subsequently, the substrate was placed in a developer solution consisting of 1 part of AZ 351B (MicroChemicals GmbH) and 3 parts of water with stirring for 120 seconds (cf. FIG. 1-2 and FIG. 1-3).

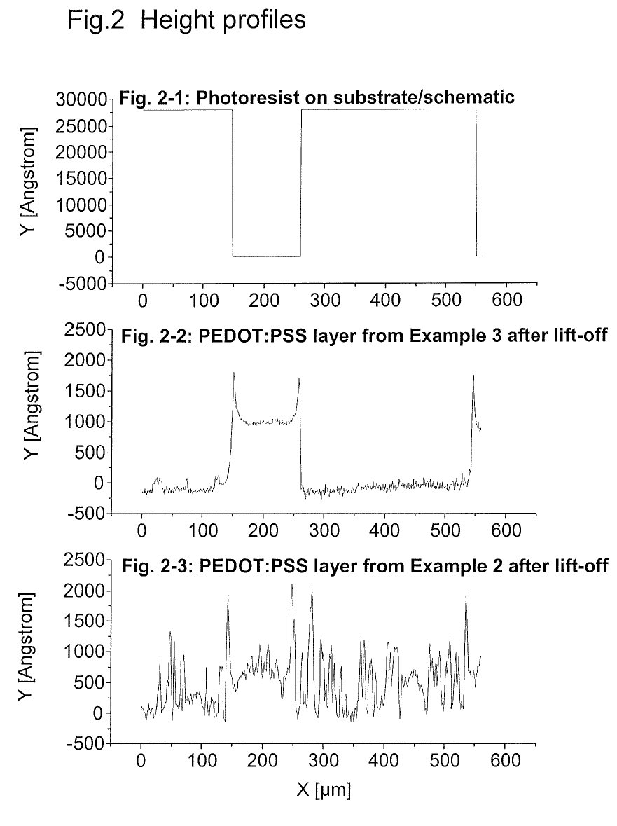

The glass substrates were then covered with structured photoresist, which left the regions which had been exposed beforehand through the shadowmask free of photoresist and the shadowed regions covered with photoresist. The height profile of the photoresist structures is shown schematically in FIG. 2-1.

### Example 2

The PEDOT:PSS dispersion was prepared in aqueous solution by a known process (L. Groenendaal, F. Jonas, D. Freitag, H. Pielartzik & J. R. Reynolds, Adv. Mater. 12 (2000) 481-494):

A 2 l three-neck flask with stirrer and internal thermometer was initially charged with 895.2 g of deionized water and 323 g of an aqueous polystyrenesulphonic acid solution with a weight-average M_{w} of 490 000 g/mol and a solids content of 5.52% by weight. The molecular weight was determined by means of aqueous gel permeation chromatography (GPC). The solution was admixed with 0.075 g of iron(III) sulphate. The reaction temperature was kept between 20 and 25° C. 2.97 g of 3,4-ethylenedioxythiophene (EDT; Baytron® M, H.C. Starck GmbH) were added with stirring. The solution was stirred for 30 minutes. Subsequently, 6.9 g of sodium persulphate were added and the solution was stirred for a further 24 hours.

On completion of the reaction, inorganic salts were removed by adding 60 g of a cation exchanger (Lewatit S100 H, Lanxess AG) and 80 g of an anion exchanger (Lewatit MP 62, Lanxess AG), and the solution was stirred for a further 2 hours. Subsequently, the ion exchanger was filtered off.

The weight ratio of PEDOT to PSS in the solution was 1:6. In order to obtain better wetting of the photoresist surface, 3 drops of a fluorosurfactant solution (F09108 Zonyl FSN, fluorinated surfactant 10% in water; ABCR GmbH) were added to 10 ml of the PEDOT:PSS solution. The solution was spin-coated onto the photoresist-structured substrate from Example 1 at 850 rpm for 30 seconds at an acceleration of 200 rev/sec² and with the lid open and then dried on a hotplate at 130° C. for 15 minutes. The layer thus obtained homogeneously covered both the photoresist-coated and -uncoated regions of the glass surface. The layer thickness d was 100 nm and the conductivity σ was 2.2 mS/cm.

Rinsing of the layer in acetone completely dissolved the crosslinked photoresist. It was possible to monitor this dissolution process visually, since the photoresist had a yellow-brownish intrinsic colour. The PEDOT:PSS layer present on the photoresist was not also removed at the same time, but rather remained on the substrate as a cohesive loose skin. This was manifested in a diffuse height profile without clearly perceptible boundaries between removed and remaining regions, as shown in FIG. 2-3. The desired lift-off of the conductive polymer layer, as shown in FIG. 1-5, thus did not take place.

### Example 3

### Inventive

The method was analogous to that in Example 2 with the difference that, this time, in the polymerization of EDT, the PSS was used with a weight-average M, of 47 000 g/mol. As in Example 2, the weight ratio of PEDOT:PSS in the solution was likewise 1:6. The solution was applied by spin-coating at 500 rpm for 30 seconds and an acceleration of 200 rev/sec² with the lid open. The layer thickness d was 100 nm and the conductivity σ was 17 mS/cm.

In contrast to Example 2, it was possible to remove the polymer layer on the crosslinked photoresist together with the crosslinked photoresist when it was rinsed in acetone. In contrast, the PEDOT:PSS layer remained adhering on the substrate. The transitions between remaining and removed regions were sharp, since the step formed here in the height profile exhibits a narrow step width of b<5 μm (cf. FIG. 2-2).

The lift-off process of the conductive polymer layer was thus performable successfully.

As the comparison of Examples 2 and 3 shows, the mean molecular weight Mw of the PSS has a considerable influence on whether the structuring of the conductive polymer layer by means of the lift-off process is successful. This structuring is successful when the PEDOT:PSS dispersion used has a PSS, referred to as short-chain PSS, with a mean molecular weight M_{w} of <100 000 g/mol. The reason for this may be that the use of this short-chain PSS allows the breaking strength of the conductive polymer layer to be lowered sufficiently that the conductive polymer layer can be removed.

### Example 4

A 2 l three-neck flask with stirrer and internal thermometer was initially charged with 868 g of deionized water and 330 g of an aqueous polystyrenesulphonic acid solution with a weight-average M_{w} of 450 000 g/mol and a solids content of 3.8% by weight. The molecular weight was deteimined by means of aqueous gel permeation chromatography (GPC). The solution was admixed with 0.075 g of iron(III) sulphate. The reaction temperature was kept between 20 and 25° C. 5.1 g of 3,4-ethylenedioxythiophene were added with stirring. The solution was stirred for 30 minutes. Subsequently, 9.5 g of sodium persulphate were added and the solution was stirred for a further 24 hours. On completion of the reaction, inorganic salts were removed by adding 120 g of a cation exchanger (Lewatit S100 H, Lanxess AG) and 80 ml of an anion exchanger (Lewatit MP 62, Lanxess AG), and the solution was stirred for a further 2 hours. The ion exchanger was filtered off. The weight ratio of PEDOT to PSS in the solution was 1:2.5.

The resulting PEDOT:PSS dispersion was homogenized five times with a high-pressure homogenizer at a pressure of 900 bar; then 95 g of this solution were mixed with 5 g of dimethyl sulphoxide.

This mixture was distributed onto the photoresist-structured substrate from Example 1. The supernatant solution was spun off at 1200 rpm over 30 seconds at an acceleration of 200 rev/sec² with the lid open. The resulting layer was dried on a hotplate at 130° C. for 10 minutes. The layer thickness d was 80 nm and the conductivity σ was 350 S/cm.

Rinsing of the layer in acetone completely dissolved the crosslinked photoresist. It was possible to monitor this dissolution process visually owing to the yellow-brownish intrinsic colour of the crosslinked photoresist. However, this did not also remove the PEDOT:PSS layer present on the photoresist, but rather it remains on the substrate as a cohesive loose skin. The desired lift-off, as shown in FIG. 1-5, thus did not take place.

### Example 5

### Inventive

The method was analogous to Example 4, with the difference that, in the polymerization, a polystyrenesulphonic acid with a weight-average M_{w} of 49 000 g/mol was used. The weight ratio of PEDOT to the PSS polymer was, as in Example 4, 1:2.5.

The PEDOT:PSS dispersion was homogenized five times with a high-pressure homogenizer at a pressure of 900 bar; then 95 g of this solution were mixed with 5 g of dimethyl sulphoxide.

This mixture was distributed onto the photoresist-structured substrate from Example 1. The supernatant solution was spun off at 1500 rpm over 30 seconds at an acceleration of 200 rev/sec² with the lid open. The resulting layer was dried on a hotplate at 130° C. for 10 minutes. The layer thickness d was 760 nm and the conductivity σ was 390 S/cm.

Rinsing of the layer in acetone completely dissolved the crosslinked photoresist. It was possible to monitor this dissolution process visually owing to the yellow-brownish intrinsic colour of the crosslinked photoresist. This removed the PEDOT/PSS layer present on the photoresist in some places. The desired lift-off, as shown in FIG. 1-5, thus took place partly.

### Example 6

### Inventive

The dispersion produced according to Example 5 was diluted with additional polystyrenesulphonic acid. The PSS used for this purpose had a weight-average M_{w} of 49 000 g/mol. The mixture was made up such that the ratio of PEDOT to PSS in the dispersion corresponded to 1:3; subsequently, 95 g of this solution were mixed with 5 g of dimethyl sulphoxide.

The solution was spun off at 1500 rpm over 30 sec at an acceleration of 200 rev/sec² with the lid open. Subsequently, the layer was dried on a hotplate at 130° C. for 15 min. The layer thickness d was 76 nm and the conductivity σ was 360 S/cm.

In contrast to Example 5, it was possible to remove this mixture completely by means of lift-off.

### Example 7

### Inventive

The dispersion produced according to Example 5 was diluted with additional polystyrenesulphonic acid. The PSS used for this purpose had a weight-average M_{w} of 49 000 g/mol. The mixture was made up such that the ratio of PEDOT to PSS in the dispersion corresponded to 1:3.5. Subsequently, 95 g of this solution were mixed with 5 g of dimethyl sulphoxide.

The solution was spun off at 1100 rpm over 30 sec at an acceleration of 200 rev/sec² with the lid open. Subsequently, the layer was dried on a hotplate at 130° C. for 15 min. The layer thickness d was 77 nm and the conductivity σ was 310 S/cm.

In contrast to Example 5, it was possible to remove this mixture completely by means of lift-off.

### Example 8

### Inventive

The dispersion produced according to Example 5 was diluted with additional polystyrenesulphonic acid. The PSS used for this purpose had a weight-average M_{w} of 49 000 g/mol. The mixture was made up such that the ratio of PEDOT to PSS in the dispersion corresponded to 1:4. Subsequently, 95 g of this solution were mixed with 5 g of dimethyl sulphoxide.

The solution was spun off at 1100 rpm over 30 sec at an acceleration of 200 rev/sec² with the lid open. Subsequently, the layer was dried on a hotplate at 130° C. for 15 min. The layer thickness d was 77 nm and the conductivity σ was 290 S/cm.

In contrast to Example 5, it was possible to remove this mixture completely by means of lift-off.

### Example 9

### Inventive

The dispersion produced according to Example 5 was diluted with additional polystyrenesulphonic acid. The PSS used for this purpose had a weight-average M_{w} of 49 000 g/mol. The mixture was made up such that the ratio of PEDOT to PSS in the dispersion corresponded to 1:4.5. Subsequently, 95 g of this solution were mixed with 5 g of dimethyl sulphoxide.

The solution was spun off at 1000 rpm over 30 sec at an acceleration of 200 rev/sec² with the lid open. Subsequently, the layer was dried on a hotplate at 130° C. for 15 min. The layer thickness d was 77 nm and the conductivity σ was 260 S/cm.

In contrast to Example 5, it was possible to remove this mixture completely by means of lift-off.

TABLE 1
Summary of the results from Examples 2-9:

| | PEDOT:PSS | M_{w} of PSS | |
|---|---|---|---|
| Example | weight ratio | [g/mol] | Lift-off |
| 2 | 1:6 | 490 000 | No |
| 3* | 1:6 | 47 000 | Yes |
| 4 | 1:2.5 | 450 000 | No |
| 5* | 1:2.5 | 49 000 | Partly |
| 6* | 1:3 | 49 000 | Yes |
| 7* | 1:3.5 | 49 000 | Yes |
| 8* | 1:4 | 49 000 | Yes |
| 9* | 1:4.5 | 49 000 | Yes |

*Inventive examples

1-10. (canceled)

11. A process comprising: (a) providing a substrate; and (b) forming a conductive structured polymer layer on a surface of the substrate, wherein forming the conductive structured polymer layer comprises applying at least one conductive polymer comprising a polycation and at least one polyanion having a mean molecular weight M_{w} of 1,000 to 100,000 g/mol using a lift-off process.

12. The process according to claim 11, wherein the polycation comprises a component selected from the group consisting of optionally substituted polythiophenes, polyanilines, polypyrroles and mixtures thereof.

13. The process according to claim 11, wherein the polycation comprises an optionally substituted polythiophene having repeating units of the general formula (I) 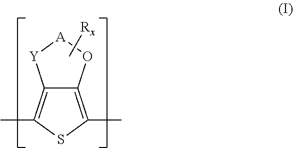
wherein A represents an optionally substituted C₁-C₅-alkylene radical; each R independently represents a linear or branched, optionally substituted C₁-C₁₈alkyl radical, an optionally substituted C₅-C₁₂-cycloalkyl radical, an optionally substituted C₆-C₁₄-aryl radical, an optionally substituted C₇-C₁₈-aralkyl radical, an optionally substituted C₁-C₄-hydroxyalkyl radical or a hydroxyl radical; and x represents an integer of 0 to 8.

14. The process according to claim 11, wherein the at least one polyanion comprises an anion of a polymeric carboxylic acid or sulphonic acid.

15. The process according to claim 13, wherein the at least one polyanion comprises an anion of a polymeric carboxylic acid or sulphonic acid.

16. The process according to claim 11, wherein the polycation comprises a polythiophene having repeating units of the general formula (Iaa) 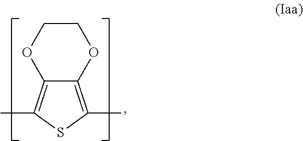
and the at least one polyanion comprises polystyrenesulphonate.

17. The process according to claim 11, wherein the mean molecular weight M_{w} of the at least one polyanion is 20,000 to 70,000 g/mol.

18. The process according to claim 13, wherein the mean molecular weight M_{w} of the at least one polyanion is 20,000 to 70,000 g/mol.

19. The process according to claim 16, wherein the mean molecular weight M_{w} of the at least one polyanion is 20,000 to 70,000 g/mol.

20. The process according to claim 11, wherein the weight ratio of the polycation to the at least one polyanion is 1:2 to 1:7.

21. The process according to claim 13, wherein the weight ratio of the polycation to the at least one polyanion is 1:2 to 1:7.

22. The process according to claim 16, wherein the weight ratio of the polycation to the at least one polyanion is 1:2 to 1:7.

23. The process according to claim 19, wherein the weight ratio of the polycation to the at least one polyanion is 1:2 to 1:7.

24. The process according to claim 11, wherein the conductive polymer layer is applied from solution or from dispersion.

25. The process according to claim 11, wherein a conductivity enhancer is added.

26. A conductive structured polymer layer prepared according to the process of claim 11.

27. A conductive structured polymer layer prepared according to the process of claim 13.

28. A conductive structured polymer layer prepared according to the process of claim 16.

29. A conductive structured polymer layer prepared according to the process of claim 19.

30. A conductive structured polymer layer prepared according to the process of claim 23.
